(19) United States
(12) Patent Application Publication
(10) Pub. No.: US 2005/0066253 A1
(43) Pub. Date: Mar. 24, 2005

(54) System and method for detecting multiple data bit errors in memory

(75) Inventors: Anthony G. Aipperspach, Rochester, MN (US); Todd A. Christensen, Rochester, MN (US); Mydung N. Pham, Austin, TX (US)

Correspondence Address: IBM CORPORATION;ROCHESTER IP LAW DEPT. 917, 3605 HIGHWAY 52 NORTH, ROCHESTER, MN, 55901-7829, US

(73) Assignee: INTERNATIONAL BUSINESS MACHINES CORPORATION, ARMONK, NY (US)

(21) Appl. No.: 10/666,031

(22) Filed: Sep. 18, 2003

(51) Int. Cl. G11C 29/00

(52) U.S. Cl. 714/763

(57) ABSTRACT

Detection of multiple data bit errors in physically adjacent data bits in a memory boundary having a parity bit, comprising activating each of a line of a memory boundary in a memory array having the parity bit; and, directing physically adjacent data bits in an activated line to two or more parity checking devices so that two or more physically adjacent data bits are not forwarded to the same one the two or more parity checking devices.

### BACKGROUND

The invention relates generally to the data processing field. More particularly, it relates to systems and methods for detecting multiple errors in memory systems.

Individual memory storage elements or cells in memory wordlines are sensitive to alpha particles, cosmic rays, or other high-energy strikes. These strikes can cause the memory storage cells to falsely switch their states (i.e., soft errors). The rate at which these errors occur is known as the Soft Error Rate (SER). Relatively high SER's can be quite serious because they lead to reliability concerns stemming from errors, such as those that effect information, and those that may ultimately cause system failure. For instance, if the memory element is within a standalone memory chip, soft errors generally cause data errors. When the memory element is utilized to define and keep the logic configuration, the SER effect becomes more serious, since it now causes functional errors.

Eliminating such errors in large systems, such as with multiple processors and the use of large banks of memory, is a major concern. SER concerns are also high when using silicon based memory devices. Despite the advent of silicon-on-insulator (SOI) Metal Oxide Semiconductor (MOS) technology, which reduces overall SER, the incidence of changing values of adjacent SOI cells increases under certain situations. In particular, the memory cells in the thinner SOI are highly susceptible to alpha particles striking at more oblique angles to the plane of the memory cell than heretofore known. Consequently, oblique angle strikes have a tendency to lead to double cell failures appearing in arrays or cache architecture.

A traditional approach utilized to detect if a cell has a changed state is a parity check at convenient boundaries, such as byte or word boundaries. However, this approach is not effective in the case of two cells in the same boundary having changed states. Approaches, such as error checking and correction codes (ECC) can be utilized. However, ECC is not entirely satisfactory since overall performance and area of circuitry are impacted negatively, as well as it is relatively costly. One lower cost alternative is the use of a folded memory array. However, folded memory wordlines have drawbacks in that it is not always convenient to fold an array because and undesirable macro form factor may result.

Therefore, there is a desire for a relatively low cost and reliable method and system of detecting the occurrence of multiple data cell errors within a given memory boundary.

### SUMMARY OF THE INVENTION

The present invention provides an enhanced apparatus and method for detecting multiple cell errors in a memory boundary in a memory array without negative effect and that overcome many of the disadvantages of prior art arrangements.

In an illustrated embodiment, a method of detecting multiple data bit errors in physically adjacent data bits in a memory boundary having a parity bit, comprising the steps of: activating each of a line of a memory boundary in a memory array having the parity bit; and, directing alternating data bits in an activated line of the memory boundary to different parity checking devices so that physically adjacent data bits are forwarded to different ones of the parity checking devices.

In an illustrated embodiment, an apparatus for use in detecting multiple data bit errors in physically adjacent data bits in a memory boundary of a memory array in response to data fetching, comprising: a memory array including a memory boundary having a parity bit in an activatable line; and, two or more parity checking devices for checking parity coupled to the memory array in a manner so that physically adjacent data bits in an activated line are forwarded to a different one of the two or more parity checking devices.

It is an aspect of the present invention for providing apparatus and methods for overcoming the drawback effects of multiple cell errors in physically adjacent cells in a memory array.

It is a further aspect of the present invention for providing reliable and low cost techniques for detecting cell errors of the above type that do not require folding of memory or utilization of error correction coding (ECC).

It is a further aspect of the present invention to provide techniques of the above type that require less overall space.

It is another aspect of the present invention for providing specific techniques for detecting double data bit errors or faults in a word or byte in wordlines of memory structure using parity checking schemes.

These and other features and aspects of the present invention will be more fully understood from the following detailed description of the preferred embodiments, which should be read in light of the accompanying drawings. It should be understood that both the foregoing generalized description and the following detailed description are exemplary, and are not restrictive of the invention.

### BRIEF DESCRIPTION OF THE DRAWINGS

FIG. 1 is a schematic view of a parity checking scheme of the prior art.

FIG. 2 is a schematic view of a parity checking scheme according to the present invention.

### DETAILED DESCRIPTION

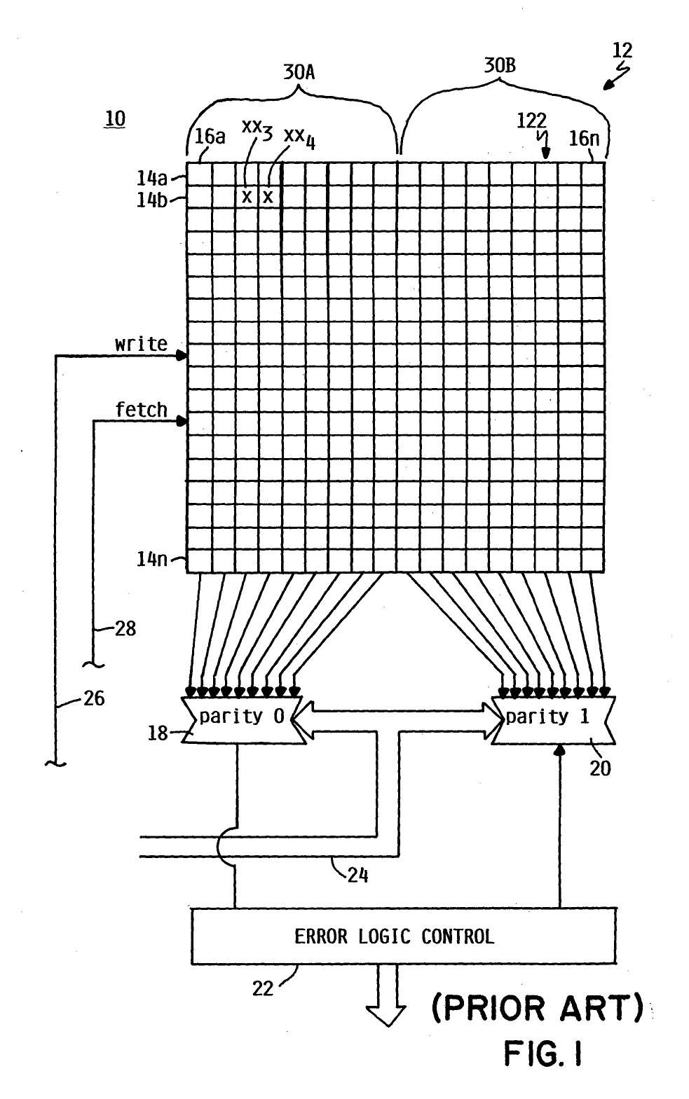

FIG. 1 is a schematic view of a prior art data processing system 10 that illustrates a known approach for detecting data errors in, for example, a computer system memory structure or array 12. The computer system memory array 12 can be any memory capable of storing data. In this embodiment, the system memory array 12 is constructed on a semiconductor type, such as silicon-on-insulator (SOI) Metal Oxide Semiconductor (MOS). In another embodiment, system memory array 12 is constructed in a semiconductor type known as bulk semiconductor. In particular, the system memory array 12 can be a random access memory, such as a SRAM (Static Random Access Memory) (e.g., a 64-megabyte or 1 gigabyte SRAM). The memory array 12 can instead be a Dynamic Random Access Memory (DRAM). The system memory array 12 has a plurality of rows of memory wordlines 14a-n. The memory array 12 includes a plurality of bit line columns 16a-n. Each of the memory wordlines 14a-n includes a plurality of memory cells xx1-n. The cells can be adversely affected by strikes of alpha particles or the like and thus subject to error. In this embodiment, the system memory array 12 is configured for storing a plurality of 8-bit words (or any other suitable size word or byte) including the storing of a parity bit for each 8-bit word in individual word groupings 30A, 30B. Only the two 8-bit word groupings 30A, 30B are depicted, however, a plurality is envisioned. In addition, other memory configurations are contemplated.

The data processing system 10 includes at least a pair of suitable parity bit generator/checker units 18 and 20; respectively. The parity bit generator/checkers can be separate generator and checking units. The parity bit generator/checker units 18 and 20 are logically disposed between the system memory array 12 and the error logic control 22. The error logic control 22 may determine the single data errors and their locations, such as in cell xx-1n in word grouping 30A. Thereafter, a data error can be corrected by any suitable error correcting mechanism (not shown). Alternatively, an error can be reported, and subsequently, computer hardware or software determines appropriate action, such as terminating operation. The parity generator/checker units 18, 20 are utilized when data is written and fetched from memory. The parity generator/checking units can be utilized with internal and external DRAM or SRAM. A single parity generator/checker unit is associated with each 8-bit word and the parity bit. In this approach, each of the data bits in separate bit line columns 16a-k in separate 8-bit words is driven to the same input of the parity generator/checking unit through appropriate signal lines. Thus, each 8-bit word including parity bit in a wordline is checked by a corresponding one of the parity generator/checker units. Accordingly, selective word groupings of each of the memory wordlines are connected to selected ones of the parity checkers.

Data from data input bus 24 of a computer system is written into the memory array after passing through the parity generator/checkers, whereby the latter generate a parity bit for storing along with each associated word. For effecting writing and fetching of the data, provisions is made for write and fetch control lines 26 and 28; respectively, which carry appropriate signals to the memory array in a known manner.

To detect data errors in the memory array 12, computation of the parity of each 8-bit word stored is performed. In the foregoing circuit arrangement during a write to the word, a single parity bit is generated by each of a pair of parity generator/checker units 18 and 20. These parity bits are stored together with each of the associated words. When a word is read, the parity is recomputed and compared with the accompanying parity bit. Detected parity differences from the parity generator/checker units alert the data processing system 100 of data errors via the error logic control circuit 22. The parity generator/checker unit 18 is, for example, an odd parity type, which both generates the appropriate parity bit as well as checks the word being read to determine if parity is correct. In odd parity, the sum or the “1's” transmitted including the parity bit will be odd. The same principle applies to the even parity generator/checker unit 20, wherein a “1” or a “0” is added as the parity bit to make the sum even. The parity generator/checker units will check to make sure that an odd number of “1's” have been received if odd parity is used or an even number of “1's” if even parity is present. If a single-bit error is detected the error logic control circuit generates a suitable interrupt bit.

The illustrated embodiment does not discuss mechanisms for correcting for the detected errors, since a number of suitable correcting schemes can be utilized. However, given the above parity checking scheme, if two physically adjacent bits, such as bits xx3, xx4 within a transmitted word 30A, are changed, detection is not possible.

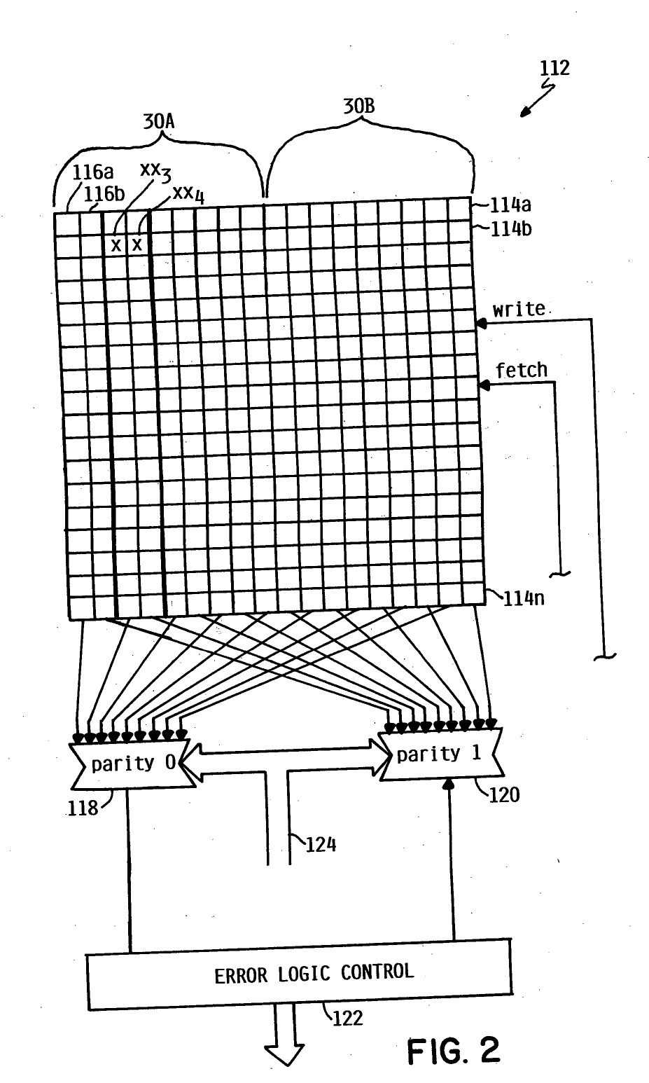

Reference is made to FIG. 2 for illustrating a preferred data processing system 100 according to the present invention. The data processing system 100 differs from the prior art in that multiple-bit memory errors in physically adjacent cells of the same boundary (e.g., word or byte) can be easily detected. It is to be understood that the multiple data bit errors that are detectable by this invention, include multiple bits physically adjacent within a memory boundary or stated differently a parity-bit associated portion of a word. Multiple bits that are considered “vertical” bits aren't included in a “memory boundary having a parity bit”.

The data processing system 100 improves over the above described prior art approaches using parity checking by providing for the retrieving of at least alternate data bits of a word to at least two different parity checkers. More particularly, the data processing system 100 provides solutions for detecting double-bit memory errors of preferably physically adjacent data bits in an activated bit line of a memory boundary having a parity bit while performing parity checking that is both reliable in operation and relatively easy and cost effective to implement.

The components of the data processing system of FIG. 1 are similar to the components of FIG. 2. Thus, those components that correspond will not be described in detail. It should be understood that the following described embodiment is only presented by way of example and should not be construed as limiting the inventive concept to any particular physical configuration.

To detect data errors in the memory array 112, computation of the parity of each word stored is performed. In performing parity checking according to this invention, the data bits of physically adjacent data cells of a word or byte are directed to a correspondingly different parity checker, whereby, for example, a double cell failure in physically adjacent cells of a word or byte can be detected. In an exemplary embodiment, a pair of parity bit generator/checkers 118 and 120 is disclosed for receiving the data bits. In this embodiment, every other data bit is directed along the bit lines 116a-n to a correspondingly different one of the pair of parity checkers 118 and 120. The present invention also encompasses situations wherein every third data bit would be sent to a third parity checker, if it is desired to determine if three physically adjacent data bits have errors. Likewise, every fourth data bit would go to a fourth parity checker, if it is desired to determine if four physically adjacent data bits have errors. Similarly, every n^{th} data bit would go to an n^{th} parity checker if it is desired to determine if n^{th} physically adjacent data bits within a boundary have errors. As a result, double-bit errors can be detected by the pair of parity checkers. As a practical matter, however, double-bit errors in physically adjacent cells would be expected to be the most prevalent multiple data bit errors. The parity bit generator/checkers 118 and 120 direct their respective outputs to the error logic control 122 which then determines the presence of the double-bit data error, whereby an interrupt bit can be generated.

The embodiments and examples set forth herein were presented to best explain the present invention and its practical applications and thereby enabling those skilled in the art to make and use the invention. However, those skilled in the art will recognize that the foregoing description and examples have been presented for the purposes of illustration and example only. The description set forth is not intended to be exhaustive or to limit the invention to the precise forms disclosed. In describing the above preferred embodiments illustrated in the drawings, specific terminology has been used for the sake of clarity. However, it is not intended that the invention be limited to the specific terms selected. In addition, each specific term includes all technical equivalents that operate in a similar manner to accomplish a similar purpose. Many modifications and variations are possible in light of the above teachings without departing from the spirit and scope of the appended claims.

1. A method of detecting multiple data bit errors in physically adjacent data bits in a memory boundary having a parity bit, comprising the steps of: activating each of a line of a memory boundary in a memory array having the parity bit; and, directing physically adjacent data bits in an activated line to two or more parity checking devices so that two or more physically adjacent data bits are not forwarded to the same one of the parity checking devices.

2. The method recited in claim 1 wherein multiple data bit errors can be determined in physically adjacent data bits by error logic control.

3. The method recited in claim 1 wherein directing includes at least a pair of parity checking devices for detecting double-bit errors in physically adjacent data bits wherein alternating data bits are directed to alternating parity checking devices.

4. An apparatus for use in detecting multiple data bit errors in physically adjacent data bits in a memory boundary of a memory array in response to data fetching, comprising: a memory array including a memory boundary having a parity bit in an activatable line; and, two or more parity checking devices for checking parity coupled to the memory array in a manner so that two or more physically adjacent data bits are not forwarded to the same one of the parity charity devices.

5. The apparatus recited in claim 4 wherein double-bit errors in physically adjacent data bits can be determined by error logic control.

6. The apparatus recited in claim 4 wherein double-bit errors are determined by a pair of parity checking devices for detecting double-bit errors in physically adjacent data bits wherein alternating data bits are directed to alternating ones of the pair of parity checking devices.

7. The apparatus recited in claim 4 wherein the memory array is constructed on a Silicon on Insulator (SOI) Metal Oxide Semiconductor (MOS).

8. The apparatus recited in claim 4 wherein the memory array is constructed on bulk silicon.
